(19) United States
(12) Patent Application Publication
(10) Pub. No.: US 2009/0163020 A1
(43) Pub. Date: Jun. 25, 2009

(54) Method for Manufacturing Semiconductor Device

(76) Inventor: Sang Wook Ryu, Cheongju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/264,303

(22) Filed: Nov. 4, 2008

(30) Foreign Application Priority Data
Dec. 21, 2007 (KR) 10-2007-0135894

(51) Int. Cl. H01L 21/4763

(52) U.S. Cl. 438/627; 257/E21.495

(57) ABSTRACT

A method for manufacturing a semiconductor device is provided. A first interlayer dielectric film can be formed on a semiconductor substrate, and a metal wire can be formed on the first interlayer dielectric film. A second interlayer dielectric film can be formed on the first interlayer dielectric film, including the metal wire. A photoresist pattern can be formed on the second interlayer dielectric film. The photoresist pattern can include a high pattern density region having a first plurality of openings, a low pattern density region having a second plurality of openings, and a dummy pattern region having a third plurality of openings. Via holes can be formed by etching the second interlayer dielectric film using the photoresist pattern as a mask.

### CROSS-REFERENCE TO RELATED APPLICATION

The present application claims the benefit under 35 U.S.C. §119 of Korean Patent Application No. 10-2007-0135894, filed Dec. 21, 2007, which is hereby incorporated by reference in its entirety.

### BACKGROUND

A dry etching process of an interlayer dielectric film may use CₓH_{y}F_{z} (where x, y, and z are nonnegative integers, which includes zero) as a basic etching gas, and oxygen gas (such as O₂) is sometimes used to adjust the C/F ratio of the basic etching gas. Nitrogen gas (N₂) is also used for forming an etching byproduct with weaker volatility than oxygen gas, and argon gas (Ar) can be used to help provide dilution of plasma, improvement of uniformity, and anisotropic dry etching by being ionized.

However, the density of via holes generally takes less than 1% of the entire wafer area. In this case, the carbon component generated from a photoresist film can be mixed with the difference in etching byproduct between a part having a relatively low number of via holes sectionally and a part having a relatively high number of via holes sectionally. Thus, the part having a relatively high via hole density can have its etching speed increased, and at the edge of the part having a relatively high via hole density, that is, in the part adjacent to the part covered with the photoresist film, the etching speed can be decreased.

This occurs because the C/F ratio of the basic etching gas can be different in different sections due to the injected gas. In other words, if there are a few dielectric films to be etched and sectionally small areas of the photoresist film, the C/F ratio lowers to increase the etching speed, whereas if there are sectionally large areas of the photoresist film, the etching speed on that area lowers to stop etching.

As a result, an opening can often occur in a metal wire, leading to an operation error in the device. In particular, such a phenomenon commonly occurs when using a gas with a very high C/F ratio, which is often used for implementing a high selectivity to a bottom layer. For example, etching using C₄F₈, C₅F₈, and C₆F₈ often exhibit this opening in a metal wire.

### BRIEF SUMMARY

Embodiments of the present invention provide methods for manufacturing a semiconductor device capable of reducing the difference in etching speed according to the pattern density of via holes.

In an embodiment, a method for manufacturing a semiconductor device can comprise: forming a first interlayer dielectric film on a semiconductor substrate; forming a metal wire on the first interlayer dielectric film; forming a second interlayer dielectric film on the first interlayer dielectric film including the metal wire; forming a photoresist pattern on the second interlayer dielectric film; and etching the second interlayer dielectric film using the photoresist pattern as a mask to form via holes for a high pattern density region and a low pattern density region, and dummy via holes for a dummy pattern region between the high pattern density region and the low pattern density region. The photoresist pattern can comprise a high pattern density region having a first plurality of openings, a low pattern density region having a second plurality of openings, and a dummy pattern region having a third plurality of openings; wherein the dummy pattern region is between the high pattern density region and the low pattern density region; and wherein the first plurality of openings has more openings than the second plurality of openings.

### BRIEF DESCRIPTION OF THE DRAWINGS

FIGS. 1 to 4 are cross-sectional views showing a method for manufacturing a semiconductor device according to an embodiment of the present invention.

### DETAILED DESCRIPTION

Hereinafter, a method for manufacturing a semiconductor device according to embodiments will be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

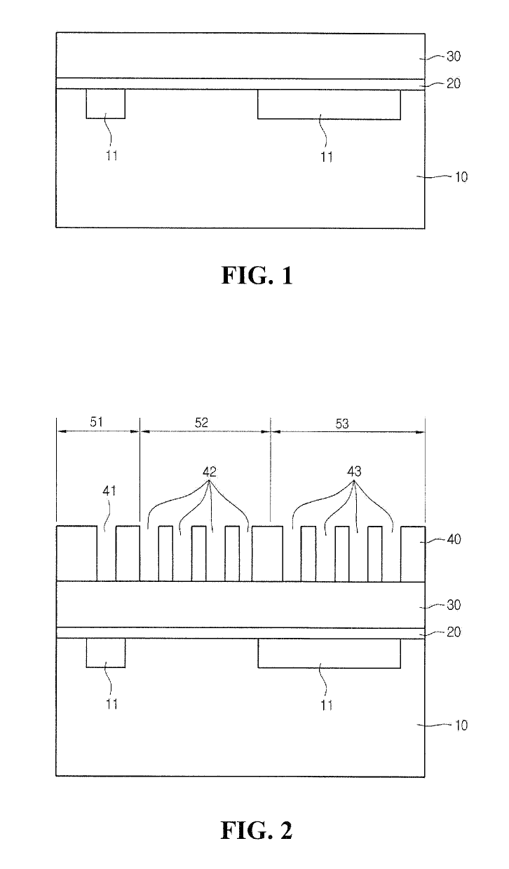

FIGS. 1 to 4 are cross-sectional views showing a method for manufacturing a semiconductor device according to embodiments.

Referring to FIG. 1, a first interlayer dielectric film 10 can be formed on a semiconductor substrate (not shown). The semiconductor substrate can include various structures, such as a transistor (not shown), a memory cell (not shown), and/or a capacitor (not shown). A metal wire 11 can be formed on the first interlayer dielectric film 10. In an embodiment, the metal wire 11 can be formed through, for example, a damascene process or photolithography and etching processes.

The first interlayer dielectric film 10 can be formed of any suitable material known in the art. For example, the first interlayer dielectric film 10 can be formed of boron phosphorus silicate glass (BPSG), phosphorus silicate glass (PSG), plasma enhanced tetraethyl orthosilicate (PETEOS), un-doped silicate glass (USG), fluorinated silicate glass (FSG), spin on glass (SOG), or any combination thereof.

The metal wire 11 can be formed of any suitable material known in the art, such as copper (Cu) or aluminum (Al).

A diffusion barrier film 20 and a second interlayer dielectric film 30 can be formed sequentially on the first interlayer dielectric film 10 including the metal wire 11.

The diffusion barrier film 20 can be formed of any suitable material known in the art. For example, the diffusion barrier film 20 can be formed of Ta, Tan, TaAlN, TaSiN, TaSi₂, Ti, TiN, TiSiN, WN, Co and CoSi₂, or any combination thereof. The diffusion barrier film 20 can also be formed by stacking at least two layers. In an embodiment, the diffusion barrier film 20 can be formed to a thickness of from about 100 Å to about 1500 Å. In one embodiment, the diffusion barrier film 20 may be omitted.

The second interlayer dielectric film 30 can be formed of any suitable material known in the art, for example, BPSG, PSG, PETEOS, USG, FSG, SOG, or any combination thereof.

In one embodiment, the second interlayer dielectric film 30 can be formed of a SiO₂-based material. The SiO₂-based material can have a dielectric constant of from about 1.5 to about 4.5. Additionally, H, F, C, and/or CH₃ can be partially coupled to the SiO₂-based material, and organic material based on C—H bonds can be included (for example, SiLK™ and Flare™).

Thereafter, in certain embodiments, a capping layer (not shown) can be formed on the second interlayer dielectric film 30. The capping layer can be formed of any suitable material known in the art, for example, SiO₂, SiC, SiN, Si₃N₄, SiOC, SiOCH, SiON, or any combination thereof. The capping layer can function as an anti-reflection film, a chemical mechanical polishing (CMP) stop layer during a subsequent CMP process, and/or a buffer during an ion implantation.

Referring to FIG. 2, a photoresist film can be formed on the second interlayer dielectric film 30, and a photoresist pattern 40 can be formed by selectively exposing and etching the photoresist film. In an embodiment, an anti-reflection film can be applied before forming the photoresist film, and a separate anti-reflection film is not required when forming the capping layer.

The photoresist pattern 40, which is a pattern for forming via holes in the second interlayer dielectric film 30, can be divided into a high pattern density region 53 and a low pattern density region 51. The high pattern density region 53 can have a first plurality of openings 43, and the low pattern density region 51 can have a second plurality of openings 41 smaller in number than the first plurality of openings 43. The first and second pluralities of openings 43 and 41 can be formed according to the design of the semiconductor device.

In an embodiment, the high pattern density region 53 and the low pattern density region 51 can each be formed over a portion of the first interlayer dielectric film 10 having a corresponding metal wire 11. That is, vias (to be formed in a subsequent step) can be provided for connection to the metal wire 11 at a high pattern density region 53 and the metal wire 11 at a low pattern density region 51.

Additionally, a dummy pattern region 52 can be formed between the high pattern density region 53 and the low pattern density region 51. The dummy pattern region 52 can have a third plurality of openings 42, and can be formed over a portion of the first interlayer dielectric film 10 that does not include a metal wire 11. The dummy pattern region 52 can help inhibit the difference in etching speed of the interlayer dielectric films generated according to the pattern density of the via holes.

That is, the dummy pattern region 52 can be formed adjacent to the low pattern density region 51 having the second plurality of openings 41, which is a relatively small number of openings, to help etch the dielectric film and reduce the areas of the photoresist film sectionally, thereby solving the problem caused by the difference in etching speed of the interlayer dielectric films.

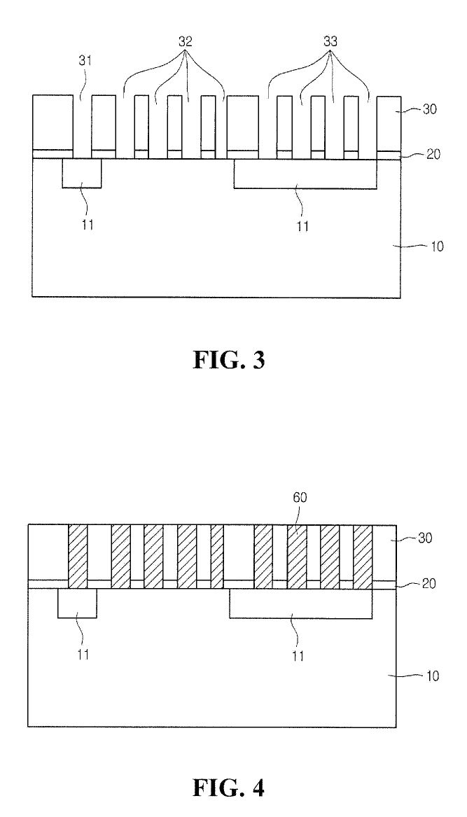

Referring to FIG. 3, the second interlayer dielectric film 30 can be etched using the photoresist pattern 40 as a mask. In an embodiment, the diffusion barrier film 20 can be etched at the same time. Also, in embodiments with a capping layer (not shown), the capping layer can be etched at the same time.

In an embodiment, the etching process of the second interlayer dielectric film 30 can use CₓH_{y}F_{z} (where x, y, and z are nonnegative numbers, which can include zero) as a basic etching gas. An etching gas can also be used that can include oxygen gas (O₂) for adjusting the C/F ratio of the basic etching gas, nitrogen gas (N₂) for forming etching byproduct with weaker volatility than oxygen gas, argon gas (Ar), or any combination thereof.

Via holes 31 and 33 can be formed in the low pattern density region 51 and high pattern density region 53, respectively, through the etching process of the second interlayer dielectric film 30. Also, dummy via holes 32 can be formed in the dummy pattern region 52.

According to embodiments of the present invention, the dummy via holes 32 can be formed in the dummy pattern region 52 adjacent to the low pattern density region 51, thereby making it possible to inhibit the problem of the etching stopping or a metal opening occurring in the via holes 31 of the low pattern density region 51.

Referring to FIG. 4, the via holes 31, 32, and 33 can be filled with a metal material to form a via 60. The top of the via 60 can be planarized through, for example, a CMP process.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
forming a first interlayer dielectric film including a metal wire;
forming a second interlayer dielectric film on the first interlayer dielectric film including the metal wire;
forming a photoresist pattern on the second interlayer dielectric film, wherein the photoresist pattern comprises a high pattern density region having a first plurality of openings, a low pattern density region having a second plurality of openings, and a dummy pattern region having a third plurality of openings; wherein the dummy pattern region is between the high pattern density region and the low pattern density region; wherein the first plurality of openings has more openings than the second plurality of openings; and
etching the second interlayer dielectric film using the photoresist pattern as a mask to form via holes corresponding to the high pattern density region and low pattern density region, and dummy via holes corresponding to the dummy pattern region.

2. The method according to claim 1, wherein the via holes are disposed corresponding to a metal wire region of the first interlayer dielectric film, and wherein the dummy via holes are disposed corresponding to the first interlayer dielectric film.

3. The method according to claim 2, wherein the metal wire is exposed through the via holes corresponding to the high pattern density region and low pattern density region, and the first interlayer dielectric film is exposed through the dummy via holes corresponding to the dummy pattern region.

4. The method according to claim 1, further comprising:
forming vias by burying a metal material in the via holes and dummy via holes.

5. The method according to claim 1, further comprising:
forming a diffusion barrier film on the first interlayer dielectric film including the metal wire before forming the second interlayer dielectric film.

6. The method according to claim 5, further comprising:
etching the diffusion barrier film using the photoresist pattern as a mask.

7. The method according to claim 5, wherein the diffusion barrier film comprises Ta, Tan, TaAlN, TaSiN, TaSi₂, Ti, TiN, TiSiN, WN, Co, CoSi₂, or any combination thereof.

8. The method according to claim 5, wherein the diffusion barrier film comprises a stack of at least two layers.

9. The method according to claim 1, wherein the first interlayer dielectric film comprises boron phosphorus silicate glass (BPSG), phosphorus silicate glass (PSG), plasma enhanced tetraethyl orthosilicate (PETEOS), un-doped silicate glass (USG), fluorinated silicate glass (FSG), spin on glass (SOG), or any combination thereof.

10. The method according to claim 1, wherein the second interlayer dielectric film comprises BPSG, PSG, PETEOS, USG, FSG, SOG, or any combination thereof.

11. The method according to claim 1, wherein the second interlayer dielectric film comprises a SiO₂-based material.

12. The method according to claim 11, wherein the SiO₂-based material has a dielectric constant of from about 1.5 to about 4.5.

13. The method according to claim 12, wherein the SiO₂-based material is partially coupled to at least one of the group consisting of: H, F, C, and CH₃.

14. The method according to claim 1, further comprising:
forming a capping layer on the second interlayer dielectric film before forming the photoresist pattern.

15. The method according to claim 14, wherein the capping layer comprises SiO₂, SiC, SiN, Si₃N₄, SiOC, SiOCH, SiON, or any combination thereof.

16. The method according to claim 1, wherein etching the second interlayer dielectric film using the photoresist pattern as a mask comprises:
using CₓH_{y}F_{z} (where x, y, and z are nonnegative integers) as a basic etching gas; and
using oxygen gas (O₂), nitrogen gas (N₂), argon gas (Ar), or any combination thereof.

17. The method according to claim 1, wherein the high pattern density region is over a portion of the first interlayer dielectric film including the metal wire; and wherein the dummy pattern region is over a portion of the first interlayer dielectric film that does not include the metal wire.

18. The method according to claim 1, wherein the third plurality of openings has more openings than the second plurality of openings.
